(19) United States
(12) Patent Application Publication
(10) Pub. No.: US 2006/0219659 A1
(43) Pub. Date: Oct. 5, 2006

(54) Method for treatment of silicon-based target object to be processed, apparatus for treatment and method of manufacturing semiconductor device

(76) Inventor: Takeshi Yamauchi, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/392,728

(22) Filed: Mar. 30, 2006

(30) Foreign Application Priority Data
Mar. 31, 2005 (JP) 2005-100326

(51) Int. Cl. C23F 1/00; H01L 21/302; B44C 1/22; H01L 21/306

(52) U.S. Cl. 216/67; 438/710; 156/345.38; 156/345.36

(57) ABSTRACT

Disclosed is a method for the treatment of a silicon-based target object to be processed, comprising the steps of exposing the silicon-based target object to a plasma atmosphere containing oxygen radicals, and applying a DC voltage to the silicon-based target object via a resistance element in an atmosphere of the plasma so as to oxidize the target object.

### CROSS-REFERENCE TO RELATED APPLICATIONS

This application is based upon and claims the benefit of priority from prior Japanese Patent Application No. 2005-100326, filed Mar. 31, 2005, the entire contents of which are incorporated herein by reference.

### BACKGROUND OF THE INVENTION

1. Field of the Invention

The present invention relates to a method for a treatment of a silicon-based target object to be processed, an apparatus for performing the treatment, and a method for manufacturing a semiconductor device.

2. Description of the Related Art

It was customary in the past to carry out a thermal oxidation treatment in which the heating is carried out at about 1,000° C. in an oxygen atmosphere for oxidizing a silicon-based target object to be processed, e.g., a silicon substrate (hereinafter referred to as a “silicon wafer”), in the manufacturing process of a semiconductor device. However, the oxidation under the temperature noted above gives rise to problems. For example, impurities are diffused into the silicon wafer. Also, stress is generated within the oxidized film.

Particularly, where the silicon wafer is doped with impurities such as As, B or P, the impurities are diffused by the heating to 1,000° C. It is certainly possible to suppress the diffusion of the impurities by lowering the heating temperature to 600° C. or lower. In this case, however, the oxidizing rate is lowered so as to make it difficult to carry out the process for forming an oxide film.

Under the circumstances, known is a method that a high frequency power or a microwave power is applied to oxygen molecules (O₂) so as to form a plasma, and the silicon wafer is oxidized at a low temperature by using the oxygen radicals (oxygen atoms) contained in the formed plasma. Since the oxygen atoms have a diffusion coefficient larger than that of the oxygen molecules, it is possible to obtain a practical oxidizing rate even under a low temperature of about 400° C.

In the low temperature oxidation process using the oxygen radical, the oxidation proceeds isotropically. Therefore, where, for example, a protruding structure is formed on a silicon wafer and the formed protruding structure is oxidized, the formed oxide film is made uniform in thickness in any of the upper portion, the side wall portion and the bottom portion of the protruding structure. As a result, where it is desired to oxidize mainly the upper portion and the bottom portion of the protruding structure and to suppress the oxidation of the side wall, it is difficult to employ the low temperature oxidizing method using the oxygen radicals.

On the other hand, in the conventional thermal oxidation method, the upper portion, the bottom portion and the side wall portion of the protruding structure formed on the silicon wafer are made different from each other in the oxidizing rate because of the difference in the planar direction of the silicon wafer, with the result that the oxidation proceeds selectively in the silicon planar direction on the upper side (generally in the (100) plane). It follows that it is possible to carry out the selective oxidation. However, the problem remains unsolved in respect of the diffusion of the impurities that is caused by the oxidation under high temperatures pointed out above.

### BRIEF SUMMARY OF THE INVENTION

According to a first aspect of the present invention, there is provided a method for a treatment of a silicon-based target object to be processed, comprising:

exposing the silicon-based target object to a plasma containing oxygen radicals; and

applying a DC voltage to the silicon-based target object via a resistance element in an atmosphere of the plasma so as to oxidize the target object.

According to a second aspect of the present invention, there is provided an apparatus for carrying out a treatment, comprising:

a process chamber;

a holder arranged within the process chamber for holding the silicon-based target object;

means for generating a plasma containing oxygen radicals within the process chamber;

a DC power source for supplying a DC voltage to the target object; and

a resistance element arranged between the target object and the DC power source.

The silicon-based target object to be processed noted above includes, for example, a silicon substrate including an irregular portion having, for example, grooves formed therein. Also, the silicon-based target object to be processed comprises a silicon substrate, an insulating film formed on the silicon substrate, and a protruding structure of silicon such as a polycrystalline silicon (polysilicon) formed on the insulating film.

Further, according to a third aspect of the present invention, there is provided a method for manufacturing a semiconductor device, comprising:

exposing a silicon substrate having a protruding portion to a plasma containing oxygen radicals; and

applying a DC voltage to the substrate via a resistance element in an atmosphere of the plasma so as to carry out the oxidizing treatment of the substrate, thereby forming oxide films on the side surface, on the upper portion and around the protruding portion such that the oxide film formed on the side surface is thinner than the oxide film formed on the upper portion and around the protruding portion.

### BRIEF DESCRIPTION OF THE SEVERAL VIEWS OF THE DRAWING

FIG. 1 is an oblique view schematically showing the construction of an apparatus for a treatment according to one embodiment of the present invention;

FIG. 2 schematically shows the conventional oxidation model performed by oxygen radicals;

FIG. 3 schematically shows the radical oxidation model that is carried out by the application of an electric field according to the embodiment of the present invention;

FIG. 4 is a cross-sectional view schematically showing the construction of a silicon wafer having a protruding structure, which is used in Example 1 of the present invention;

FIG. 5 is a graph showing the relationship in Example 1 of the present invention among the DC voltage, the thickness of the oxide film on the bottom portion and the side portion of the protruding portion, and the ratio of (thickness of the oxide film on the side portion)/(thickness of the oxide film on the bottom portion);

FIG. 6 is a cross-sectional view showing a silicon wafer having a protruding structure for explaining the facet for Example 1 of the present invention and Comparative Example 1;

FIG. 7 is a graph showing the relationship between the high frequency power and the oxidizing rate of the silicon wafer and the relationship between the high frequency power and the facet for Comparative Example 1; and

FIG. 8 is a graph showing the relationship between the high frequency power and the oxidizing rate of the silicon wafer and the relationship between the high frequency power and the facet for Example 1 of the present invention.

### DETAILED DESCRIPTION OF THE INVENTION

An embodiment of the present invention will now be described in detail.

FIG. 1 is an oblique view schematically showing the construction of an apparatus for a treatment according to an embodiment of the present invention.

As shown in the drawing, a vacuum chamber 1 comprises, for example, a rectangular process chamber 2 for applying an oxidizing treatment to a silicon-based target object to be processed, and, for example, a cylindrical plasma-forming chamber 3 arranged in a manner to communicate with an upper portion of the process chamber 2. An exhaust pipe (not shown) that is evacuated by a vacuum pump is connected to the process chamber 2. A disc-like holder 4 having a heater buried therein is arranged within the process chamber 2. A DC power source 5 is connected to the holder 4 via a resistance element 6. It is desirable for the resistance element 6 to have a resistance of 0.5 to 1.5 MΩ.

A gas supply pipe 7 is connected to the side wall in the upper portion of the plasma-forming chamber 3. A dielectric window 8 made of a quartz glass that permits transmitting microwaves is mounted so as to be positioned in an upper portion of the plasma-forming chamber 3. A rectangular waveguide 9 is mounted such that the microwave-emitting side of the waveguide 9 is in contact with the dielectric window 8. The waveguide 9 has a plane (H plane) perpendicular to the direction of the electric field of the microwaves that are transmitted within the waveguide 9, a plane (E plane) parallel to the direction of the electric field of the microwaves and, thus, perpendicular to the H plane noted above, and a reflecting plane perpendicular to each of the H plane and the E plane and reflecting the microwaves on the microwave introducing side and the opposite side. Two parallel slits 10 are formed on the H plane of the waveguide 9 facing the dielectric window 8. The microwaves propagated into the waveguide 9 are emitted into the plasma-forming chamber 3 through the slits 10 and the dielectric window 8.

Described below is the method for the oxidizing treatment of a silicon-based target object, e.g., a silicon substrate (silicon wafer) having a protruding portion formed by the process to form, for example, a groove. Naturally, the oxidizing treatment is carried out by using the apparatus for the treatment described above.

In the first step, a silicon wafer 11 of the construction described above is held by the holder 4 within the process chamber 2. Then, the silicon wafer 11 is heated by the heater buried in the holder 4. Under this condition, the vacuum pump is operated so as to discharge the gas within the vacuum chamber 1 to the outside through the exhaust pipe (not shown). At the same time, a gaseous material containing oxygen, e.g., a mixed gas prepared by diluting oxygen gas (O₂) with argon gas (Ar), is supplied through the gas supply pipe 7 into the plasma-forming chamber 3 of the vacuum chamber 1.

When the inner pressure of the vacuum chamber 1 has reached a prescribed pressure, microwaves are guided from a microwave power source (not shown) into the rectangular waveguide 9 and, then, the microwaves are emitted into the plasma-forming chamber 3 through the slits 10 and the dielectric window 8. By the electric field of the microwaves, the Ar gas and the O₂ gas are ionized so as to generate electrons, thereby forming a plasma having a high electron density (e.g., at least 10¹¹ cm⁻³). In this case, Ar ions, O₂ ions, O ions, O atoms (radicals) and electrons are formed in the plasma. The O atoms are formed by the ionization of the O₂ molecules that is caused by the collision of electrons against the O₂ molecules. The O atoms are in the excited state and, thus, are activated so as to exhibit a high reactivity. The O atom under the particular state is called an oxygen radical.

Even if a DC voltage is applied from the DC voltage source 5 directly to the holder 4 before or after generation of the plasma noted above, the DC voltage is not applied to the silicon wafer 11 in the case where a native oxide film is formed on the exposed surface of the silicon wafer 11. If the DC voltage that is applied is increased, insulation breakdown occurs making the plasma unstable (abnormal discharge). Such being the situation, the DC voltage can be applied directly to the silicon wafer 11 by applying a DC voltage, e.g., a positive DC voltage, to the holder 4 via the resistance element 6. As a result, the silicon wafer 11 heated by the heater and having the positive DC voltage applied thereto is allowed to react with the oxygen radical formed within the plasma so as to carry out an anisotropic oxidation.

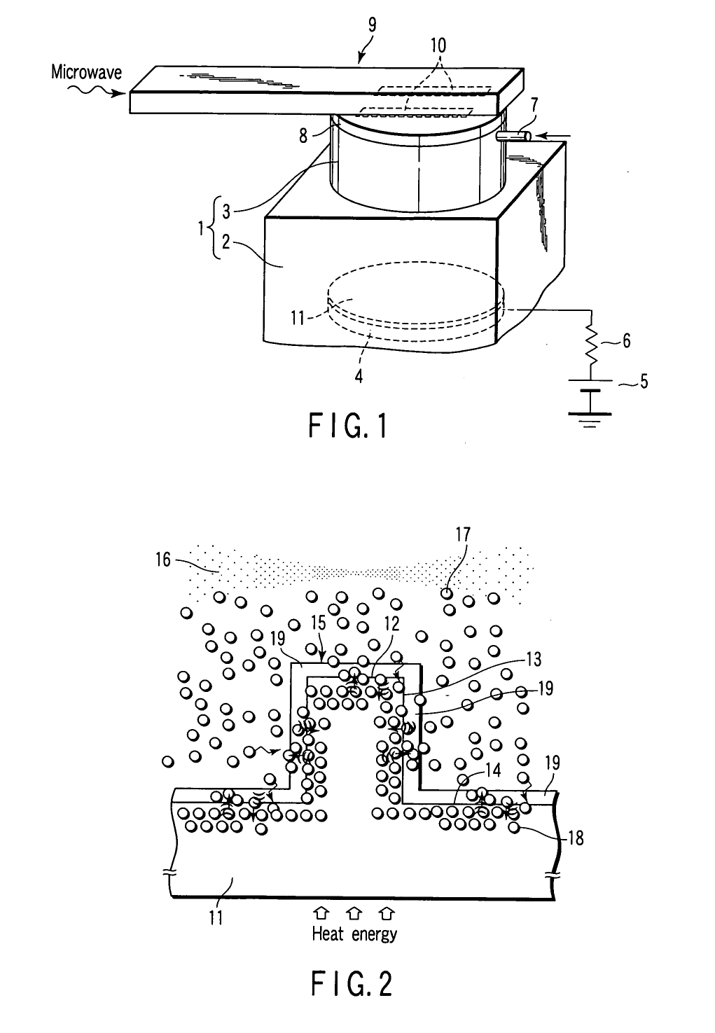

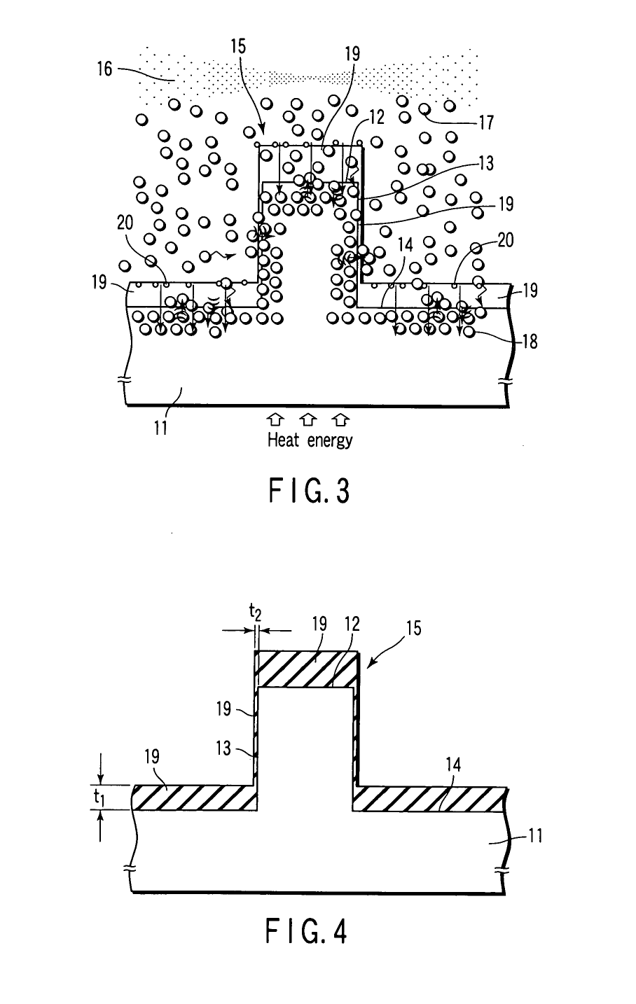

Described in detail below is the case where the anisotropic oxidation treatment is carried out by the method of this embodiment of the present invention described above in comparison with the case where the oxidation treatment of the silicon wafer is carried out by utilizing the oxygen radical alone. FIG. 2 shows as a model the oxidation of the silicon substrate that is carried out by the oxygen radical alone, and FIG. 3 shows as a model the anisotropic oxidation carried out by this embodiment of the present invention. Incidentally, the silicon wafer 11 shown in each of FIGS. 2 and 3 has an upper portion 12 and a side portion 13 so as to form a protruding portion 15 in which the surface of the silicon wafer 11 forms a bottom portion 14.

If the silicon wafer 11 is exposed to a plasma 16 in the method shown in FIG. 2, which is directed to the oxidizing treatment of the silicon wafer by using the oxygen radical alone, oxygen radicals 17 are diffused because of the thermal agitation within the plasma 16 so as to reach the silicon wafer 11. In general, the neutral particles such as radicals have a temperature substantially equal to that of the wall of the chamber, which is about 300 to 400K. In addition, the radicals are electrically neutral. Such being the situation, the oxygen radicals are not accelerated by the electric field. As a result, the thermal agitation is directed at random, with the result that the oxidation of Si18, which is a constituting element of the silicon wafer 11, proceeds without exhibiting the directivity on the surface of the silicon wafer 11 including the protruding portion 15. It follows that the oxidation proceeds substantially uniformly on the upper portion 12, the side portion 13 and the bottom portion 14 of the protruding portion 15, with the result that an oxide film 19 formed by the oxidizing effect produced by the oxygen radical is made substantially uniform in thickness.

On the other hand, in the method shown in FIG. 3, which is directed to the oxidizing treatment of the present invention in which a positive DC voltage is applied to the silicon wafer 11, the positive DC voltage applied from the DC power source 5 to the silicon wafer 11 is scarcely dropped so as to be applied to the oxide film 19 formed on the surface of the silicon wafer 11 because the silicon wafer 11 is formed of a semiconductor having a volume resistivity of about several Ω·cm. The electrons 20 within the plasma 16 are attracted by the DC voltage in a manner to have a directivity such that the electrons are attracted toward the oxide film 19 so as to be attached selectively to the upper portion 12 and the bottom portion 14 of the protruding portion 15. In other words, the electrons are unlikely to be attached to the side portion 13 of the protruding portion 15. The electrons attached to the protruding portion 15 cause the voltage of, for example, several volts to scores of volts to be generated on the surface of the oxide film 19, with the result that an electric field is generated between the surface of the oxide film 19 and the silicon wafer 11. The electric field thus generated ionizes the Si 18, which is a constituting element of the silicon wafer 11, and the ions thus formed are diffused into the oxide film 19 so as to promote the oxidation. Since the intensity of the electric field noted above is proportional to the attached amount of the electrons 20, the intensity of the electric field is rendered high in the upper portion 12 and the bottom portion 14 of the protruding portion 15 and is rendered low in the side portion 13. As a result, the oxidation promoting effect produced by the electric field having a high intensity is generated on the upper portion 12 and the bottom portion 14 of the projection 15, with the result that the oxide film 19 is formed thick on the upper portion 12 and the bottom portion 14 of the projection 15. On the other hand, the oxidation promoting effect produced by the electric field is low on the side portion 13 of the protruding portion 15. The oxide film is formed on the side portion 13 of the protruding portion 15 by the oxidation effect produced mainly by the oxygen radicals alone, with the result that the oxide film 19 is formed thin on the side portion 13 of the protruding portion 15. It follows that an anisotropic oxidation is carried out by the particular function described above such that the thick oxide film 19 is formed on the upper portion 12 and the bottom portion 14 of the protruding portion 15 and the thin oxide film 19 is formed on the side portion 13 of the protruding portion 15.

It should also be noted that the sputtering phenomenon can be suppressed or prevented on the protruding portion 15 so as to make it possible to apply a satisfactory anisotropic oxidation to the silicon wafer 11 including the protruding portion 15.

In this embodiment, the heating temperature of the silicon wafer can be made sufficiently lower than 1,000° C., at which the impurities doped in the silicon wafer are diffused, by employing the oxidation by the oxygen radical. To be more specific, the heating temperature noted above can be lowered to, for example, 400 to 600° C.

In the present invention, a gas containing an oxygen gas is introduced into the plasma-forming chamber. It is desirable for the oxygen-containing gas to be formed of a mixed gas containing oxygen gas and a rare gas such as helium, neon, argon, krypton, or xenon. Particularly, it is desirable for the oxygen content of the mixed gas to be not higher than 6% by volume, preferably, to fall within a range of 0.5 to 6% by volume. In the case of using the mixed gas having the oxygen content noted above, it is possible to generate in the formed plasma a large amount of electrons that are involved in the formation of the electric field, with the result that the anisotropic oxidation can be performed more easily. Among the rare gas elements pointed out above, it is particularly desirable to use argon because the argon gas is cheap and permits increasing the amount of electrons that are generated and contained in the formed plasma.

It is desirable for the DC voltage to be applied to the holder (or the silicon wafer supported by the holder) via a resistance element having a resistance value of 0.5 to 1.5 MΩ.

It is desirable to apply a DC voltage of −1.0 to 1.0 kV to the resistance element having a resistance value of, for example, 0.5 to 1.5 MΩ, so as to inject −2 to 2 mA of current into the silicon wafer. If the value of the injected current is smaller than −2 mA, the anisotropic oxidation tends to be made difficult. On the other hand, if the value of the injected current exceeds 2 mA, pin holes are likely to be generated in the resultant oxide film so as to lower the film quality.

In applying a DC voltage to the silicon wafer, it is desirable to apply a positive DC voltage to the silicon wafer. In the case of applying a positive voltage to the silicon wafer, it is possible to apply efficiently the electric field to the electrons present in the plasma so as to facilitate the anisotropic oxidation more efficiently.

As described above, in this embodiment of the present invention, a silicon-based target object to be processed such as a silicon wafer having a protruding portion is exposed to a plasma atmosphere containing oxygen radicals, and a DC voltage is applied to the substrate under the plasma atmosphere via a resistance element. Because of the particular treatments, the DC current can be applied directly to the silicon-based target object even if a native oxide film is formed on the exposed surface of the silicon-based target object. By the application of such a DC voltage, the silicon-based target object can be subjected to the anisotropic oxidation under temperatures lower than 1,000° C., e.g., 400 to 600° C., at which the diffusion of the impurities of the silicon-based target object can be suppressed.

According to this embodiment, it is also possible to provide an apparatus for the treatment, in which the anisotropic oxidation of the silicon-based target object can be performed.

Further, according to this embodiment, a silicon substrate having a protruding portion such as a silicon wafer is exposed to a plasma containing oxygen radicals, and a DC voltage is applied to the silicon wafer via a resistance element. The particular technique makes it possible to carry out an anisotropic oxidation of the silicon wafer having a protruding portion without giving rise to a sputtering phenomenon in the protruding portion, i.e., without bringing about a change in the shape of the protruding portion. It is possible to apply the particular method of the anisotropic oxidation to, for example, the formation of a buried element-separating region in the oxidizing step of the inner surface of a groove and to the formation of an oxide film in the periphery of the gate electrode in the manufacturing process of a semiconductor device.

Incidentally, in the embodiment described above, a waveguide for guiding microwaves into the plasma-forming chamber included in the vacuum chamber is used as the plasma generating means. However, it is also possible to use an inductively coupled plasma (ICP) as the plasma generating means.

Described below is an Example of the present invention.

### EXAMPLE 1

Prepared was a silicon wafer 11 having a protruding portion 15 including an upper portion 12, a side portion 13 and a bottom portion 14 formed of the upper surface of the silicon wafer 11. The silicon wafer 11 was disposed on the holder 4 arranged within the process chamber 2 included in the apparatus for the treatment shown in FIG. 1 referred to previously. Then, the silicon wafer 11 was heated to 400° C. by the heater buried in the holder 4. Under the particular state, the vacuum pump was operated so as to discharge the gas within the vacuum chamber 1 to the outside via the exhaust pipe (not shown). At the same time, a mixed gas consisting of argon gas and oxygen gas was supplied into the plasma-forming chamber 3 positioned in an upper portion of the vacuum chamber 1 at a flow rate of about 510 sccm. The mixed gas was prepared such that the amount of the oxygen gas based on the sum of the mixed gas (O₂/Ar+O₂) was set at 1.4% by volume. When the pressure inside the vacuum chamber 1 was set at 150 Pa, a DC voltage of −1.0 to 1.0 kV was applied from the DC voltage source 5 to the silicon wafer 11 via the resistance element 6 having a resistance of 1.5 MΩ. Before or after application of the DC voltage, microwaves having a power of 2 kW were introduced from the microwave source (not shown) into the rectangular waveguide 9 so as to permit the microwaves to be emitted into the plasma-forming chamber 3 via the slits 10 and the dielectric window 8. As a result, a plasma having an electron density of 3×10¹¹ cm⁻³ was generated within the plasma-forming chamber 3, thereby applying an oxidizing treatment to the silicon wafer 11 for 5 minutes.

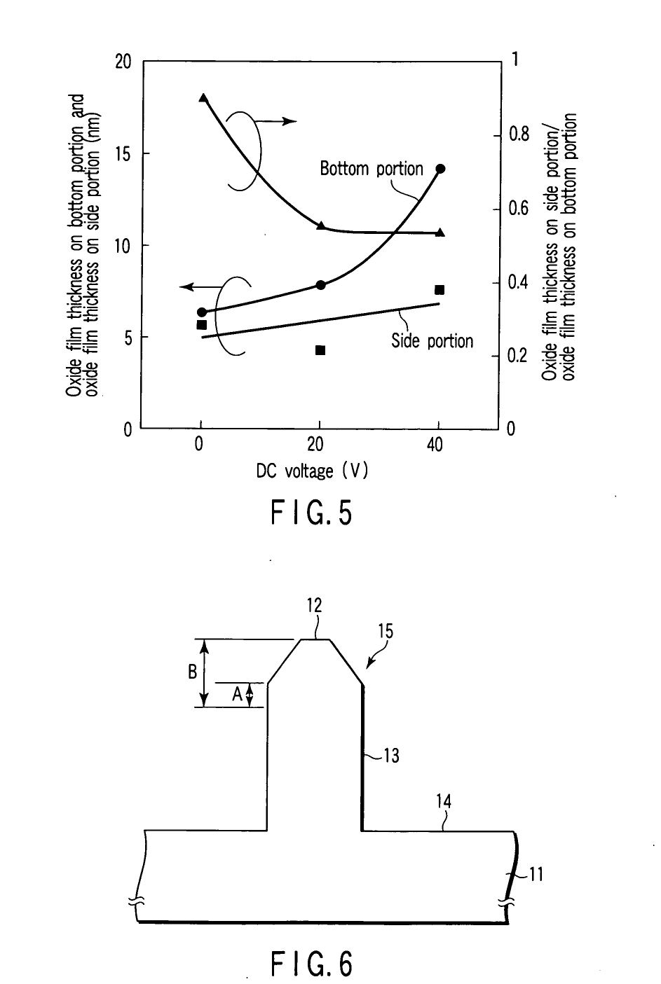

Concerning the silicon wafer 11 after the oxidizing treatment, measured were a thickness t1 of the oxide film formed in the bottom portion 14 and a thickness t2 of the oxide film in the side portion 13 of the protruding portion 15 shown in FIG. 4. FIG. 5 is a graph showing the result. In the graph of FIG. 5, the DC voltage applied to the resistance element is plotted on the abscissa, the thicknesses of the oxide films formed on the bottom portion and on the side portion of the protruding portion 15 are plotted on the left side ordinate, and the ratio of the thickness of the oxide film formed on the side portion to the thickness of the oxide film formed on the bottom portion of the protruding portion 15 is plotted on the right side ordinate.

As apparent from FIG. 5, if a DC bias voltage is applied to the silicon wafer, the thickness t₁ of the oxide film formed on the bottom portion 14 is increased, though the change in thickness t2 of the oxide film formed on the side portion 13 of the protruding portion 15 shown in FIG. 4 is small, compared with the case where a DC bias voltage is not applied to the silicon wafer. The experimental data clearly support that it was possible to achieve an anisotropic oxidation. In particular, the thickness t₁ of the oxide film 19 formed on the bottom portion 14 was prominently increased in the case where the DC bias voltage, i.e., the DC bias voltage applied to the resistance element, fell within a range of −1.0 kV to 1.0 kV. In addition, the ratio in the thickness of the oxide film formed on the side portion 13 to the thickness of the oxide film formed on the bottom portion 14 was decreased, supporting that it was possible to carry out the oxidation with a higher anisotropy.

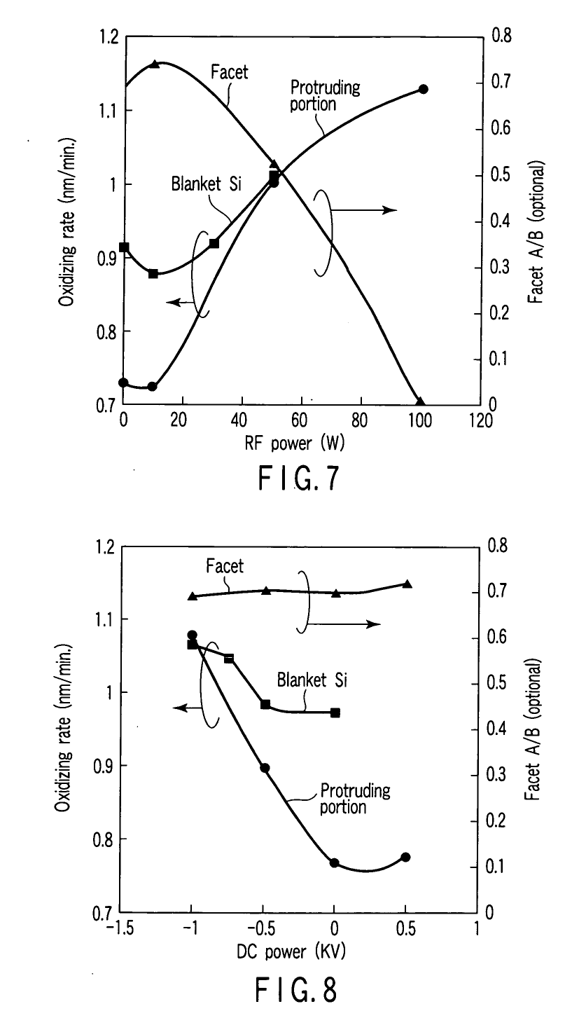

Also, as Comparative Example 1, a similar oxidizing treatment was carried out as in Example 1, except that high-frequency power of 13.56 MHz was applied in place of the DC voltage from a high-frequency power source directly to the holder 4. Examined were the relationship between the high-frequency power and the oxidizing rate of the silicon wafer and the relationship between the high-frequency power and the amount of the upper shoulder portion, which was taken off by the sputtering, in the protruding portion of the silicon wafer after the oxidizing treatment. The amount of the upper shoulder portion that was taken off by the sputtering was obtained from the facet A/B shown in FIG. 6 of the upper shoulder portion in the protruding portion 15 of the silicon wafer 11 after the oxidizing treatment. FIG. 7 is a graph showing the experimental data.

Further examined were the relationship between the DC voltage, which was supplied from the DC power source, and the oxidizing rate of the silicon wafer and the relationship between the DC voltage and the amount of the upper shoulder portion, which was taken off by the sputtering, in the protruding portion of the silicon wafer after the oxidizing treatment, i.e., the facet A/B shown in FIG. 6. FIG. 8 is a graph showing the experimental data.

As apparent from FIG. 7, in Comparative Example 1, in which high-frequency power was applied directly to the silicon wafer, the oxidizing rate was increased with increase in the high-frequency power. However, the facet was also increased, indicating that the shape of the protruding portion was changed. It should be noted in this connection that the ions formed within the plasma are attracted toward the silicon wafer by the self bias potential formed by the high-frequency electric field, and the attracted ions collide against the wafer so as to bring about the sputtering phenomenon, with the result that the shape of the protruding portion is changed as pointed out above. Particularly, the sputter yield is high in the upper corner of the projection portion, with the result that the upper corner of the protruding portion tends to be taken off and so as to deform the protruding portion.

On the other hand, in Example 1, in which a DC voltage was applied to the silicon wafer via the resistance element having a resistance of 1.5 MΩ, it was possible to form a plasma without bringing about an abnormal discharge so as to make it possible to execute the anisotropic oxidation described previously. It should be noted in particular that the facet remains substantially constant as shown in FIG. 8, though the oxidizing rate is increased by the application of a DC voltage up to −1.0 kV. This implies that the sputtering phenomenon is scarcely brought about by the application of a DC voltage. It follows that the application of the DC voltage permits the anisotropic oxidation to be performed without causing a change in the shape of the protruding portion unlike the application of high-frequency power.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for a treatment of a silicon-based target object to be processed, comprising:
exposing the silicon-based target object to a plasma atmosphere containing oxygen radicals; and
applying a DC voltage to the silicon-based target object via a resistance element in an atmosphere of the plasma so as to oxidize the target object.

2. The method according to claim 1, wherein the silicon-based target object is formed of a silicon substrate having an irregular portion in which a groove is formed.

3. The method according to claim 1, wherein the silicon-based target object comprises a silicon substrate, an insulating film formed on the substrate, and a protruding structure made of silicon and formed on the insulating film.

4. The method according to claim 1, wherein the plasma is generated by applying an electric field of microwaves to a gaseous material containing an oxygen gas.

5. The method according to claim 4, wherein the gaseous material containing oxygen gas is a mixed gas consisting of oxygen gas and at least one rare gas element selected from the group consisting of helium, neon, argon, krypton and xenon.

6. The method according to claim 5, wherein the mixed gas contains oxygen gas in an amount not larger than 6% by volume.

7. The method according to claim 5, wherein the mixed gas contains oxygen gas in an amount of 0.5 to 6% by volume.

8. The method according to claim 5, wherein argon is used as the rare gas element.

9. The method according to claim 1, wherein the target object to be processed is heated to 400 to 600° C.

10. The method according to claim 1, wherein the resistance element has a resistance of 0.5 to 1.5 MΩ.

11. The method according to claim 1, wherein the DC voltage applied to the target object to be processed is a positive DC voltage.

12. An apparatus for performing a treatment, comprising:
a process chamber;
a holder arranged within the process chamber for holding a silicon-based target object;
means for generating a plasma containing oxygen radicals within the process chamber;
a DC power source for supplying a DC voltage to the target object; and
a resistance element arranged between the target object and the DC power source.

13. The apparatus according to claim 12, wherein the resistance element has a resistance of 0.5 to 1.5 MΩ.

14. A method for manufacturing a semiconductor device, comprising:
exposing a silicon substrate having a protruding portion to a plasma containing oxygen radicals; and
applying a DC voltage to the substrate via a resistance element in an atmosphere of the plasma so as to carry out the oxidizing treatment of the substrate, thereby forming oxide films on the side surface and the upper surface of the protruding portion and around the protruding portion such that the oxide film formed on the side surface of the protruding portion is thinner than any of the oxide films formed on the upper surface of the protruding portion and around the protruding portion.

15. The method according to claim 14, wherein the plasma is generated by applying an electric field of microwaves to a gaseous material containing an oxygen gas.

16. The method according to claim 15, wherein the gaseous material containing oxygen gas is a mixed gas consisting of oxygen gas and at least one kind of a rare gas element selected from the group consisting of helium, neon, argon, krypton, and xenon.

17. The method according to claim 16, wherein the amount of the oxygen gas contained in the mixed gas is not larger than 6% by volume.

18. The method according to claim 16, wherein the amount of the oxygen gas contained in the mixed gas is 0.5 to 6% by volume.

19. The method according to claim 16, wherein argon is used as the rare gas element.

20. The method according to claim 14, wherein the substrate is heated to 400 to 600° C.

21. The method according to claim 14, wherein the resistance element has a resistance of 0.5 to 1.5 MΩ.
